(19) United States
(12) Patent Application Publication
(10) Pub. No.: US 2026/0052906 A1
(43) Pub. Date: Feb. 19, 2026

(54) METHOD FOR PROCESSING A SUBSTRATE

(71) Applicant: TEL Manufacturing and Engineering of America, Inc., Chaska, MN (US)

(72) Inventors: Wei-Jung Lai, North Chelmsford, MA (US); Jeffrey Landfried, North Chelmsford, MA (US); Allen Leith, North Chelmsford, MA (US)

(21) Appl. No.: 18/807,702

(22) Filed: Aug. 16, 2024

(51) Int. Cl. H10N 30/082

(52) U.S. Cl. CPC H10N 30/082

(57) ABSTRACT

A method for processing a substrate includes bombarding the substrate with a local substrate processing tool. A top surface of the substrate includes lithium. After bombarding the top surface with the local substrate processing tool, a co-gas including an acidic gas is flowed over the substrate.

### TECHNICAL FIELD

The present invention relates generally to electronics manufacturing, and, in particular embodiments, to a system and method for processing a substrate.

### BACKGROUND

Piezoelectric devices play a pivotal role in a multitude of technological applications, ranging from telecommunications to medical imaging. These devices rely on the piezoelectric effect, where mechanical stress induces an electric charge within certain materials, to convert electrical energy into mechanical motion or vice versa. Among the materials used in piezoelectric devices, lithium-containing materials such as lithium tantalate (LiTaO₃) and lithium niobate (LiNbO₃) have advantageous piezoelectric properties, including high electromechanical coupling coefficients and stable temperature behavior.

However, the performance of piezoelectric devices may depend on the precise control of their material properties, such as resonance frequency, bandwidth, and quality factor. Achieving these specifications often necessitates meticulous tuning or “trimming” of the piezoelectric material. Traditionally, this trimming process involves laborious techniques such as mechanical lapping or chemical etching, which are not only time-consuming but also prone to introducing defects that degrade device performance.

To address these challenges, there is a growing interest in developing more efficient and precise trimming methods for lithium-based substrates used for piezoelectric devices. These methods aim to achieve targeted adjustments to the material's properties while minimizing damage and maintaining device integrity.

### SUMMARY

In accordance with an embodiment, a method for processing a substrate includes: bombarding the substrate with a local substrate processing tool, a top surface of the substrate including lithium; and after bombarding the top surface with the local substrate processing tool, flowing a co-gas including an acidic gas over the substrate.

In accordance with another embodiment, a method for processing a substrate includes: providing the substrate into a process chamber, a top surface of the substrate including lithium; and performing a trimming process on the top surface of the substrate, the trimming process including: forming a reactive surface layer over the top surface with a gas cluster beam; and removing the reactive surface layer by flowing an acidic gas in combination with a carrier gas.

In accordance with yet another embodiment, a system includes: a process chamber, the process chamber including a substrate holder; a gas flow system coupled with the process chamber, the gas flow system being configured to bombard a substrate disposed on the substrate holder with a flux of gas clusters; and a co-gas supply system, the co-gas supply system being configured to supply an acidic co-gas to the substrate, the acidic co-gas reacting with a top surface of the substrate exposed to the gas clusters.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a cross-sectional view of a system for processing a substrate, in accordance with an embodiment;

FIG. 1B illustrates a diagram of a co-gas supply system, in accordance with an embodiment;

FIG. 2 illustrates a cross-sectional view of a substrate during an intermediate stage of a trimming process, in accordance with an embodiment;

FIG. 3 illustrates a cross-sectional view of a substrate during an intermediate stage of a trimming process, in accordance with an embodiment;

FIG. 4A illustrates a cross-sectional view of a substrate during an intermediate stage of a trimming process, in accordance with an embodiment;

FIG. 4B illustrates a chemical diagram of an exemplary acidic gas, in accordance with some embodiments;

FIG. 5 illustrates a cross-sectional view of a substrate during an intermediate stage of a trimming process, in accordance with an embodiment;

FIG. 6 illustrates a process flow chart diagram of a method for processing a substrate, in accordance with some embodiments; and

FIG. 7 illustrates a process flow chart diagram of a method for processing a substrate, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

This disclosure describes processing a substrate with gas cluster assisted trimming processes. The gas cluster assisted trimming processing technique, described herein in various embodiments, is a hybrid gas cluster and acidic gas processing method. In various embodiments of this method, radicals are delivered by a flux of gas clusters close to a top surface of the substrate, and the acidic gas is flowed toward the substrate to react with the radicals and thereby trim the top surface of the substrate.

According to one or more embodiments of the present disclosure, this application relates to methods of trimming a substrate with a local substrate processing tool enhanced with a co-gas. Lithium-containing substrates (e.g., substrates comprising lithium tantalate (LiTaO₃), lithium niobate (LiNbO₃), or the like) may be etched during electronics processing, such as to manufacture piezoelectric devices (e.g., surface acoustic wave devices). Etching of the lithium-containing material can be enhanced by using a local substrate processing tool. The advantages of using the described method may stem from the local substrate processing capability of the processing tool, which refers to a capability of controllably altering processing parameters locally. In other words, a controlled process parameter of an local substrate processing process may be a function of coordinates of a location on the surface of the substrate. This allows the surface preparation processes to adjust the process conditions dynamically to achieve a desired surface characteristic, such as a desired surface topography (e.g., planarity, divot, and bump) or distribution of surface adhesion energy (i.e., surface activation).

In some embodiments, the local substrate processing tool is a fluorine-containing gas cluster beam. However, chemical reactions between the lithium-containing material and the fluorine-containing gas cluster beam may lead to a rougher surface and degradation of surface crystallinity of the lithium-containing material. The rougher surface may be due to a reaction of fluorine from the gas cluster beam with lithium to form lithium fluoride (LiF) residues. These lithium fluoride (LiF) residues may produce heterogeneous surfaces which promote continuous etching. Degradation in surface crystallinity of the lithium-containing material may result from energy of the gas cluster beam converting crystalline surfaces into amorphous surfaces. Both of these issues may be addressed by the addition of a co-gas, such as an acidic gas (e.g., pentafluoropropionic acid). The addition of the co-gas into the fluorine-containing gas cluster beam may create hydrogen fluoride (HF) to remove lithium fluoride (LiF) residues, thereby producing a smoother surface. The addition of the co-gas into the fluorine-containing gas cluster beam may further remove an amorphous oxide layer (e.g., tantalum oxide (TaOₓ), niobium oxide (NbOₓ), or the like), thereby reducing or eliminating the degradation in surface crystallinity.

Although the described embodiments have used gas cluster beam (GCB) as examples of local substrate processes, it is understood that persons skilled in the art may apply the methods described in this disclosure to develop similar local substrate processes using some other local surface preparation technique such as neutral particle beam, electron beam, ion beam (e.g., a monoatomic ion beam), and plasma torch processing. The particle flux may be generated using radio frequency (RF) plasma, microwave plasma, DC electric field, or a gas nozzle. Embodiments of the disclosure, such as the addition of an acidic co-gas, may be used with any suitable local substrate process.

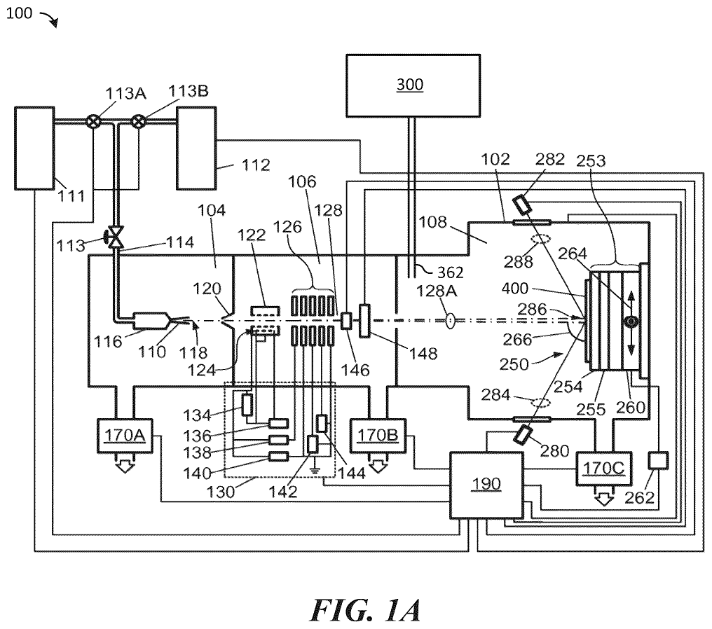

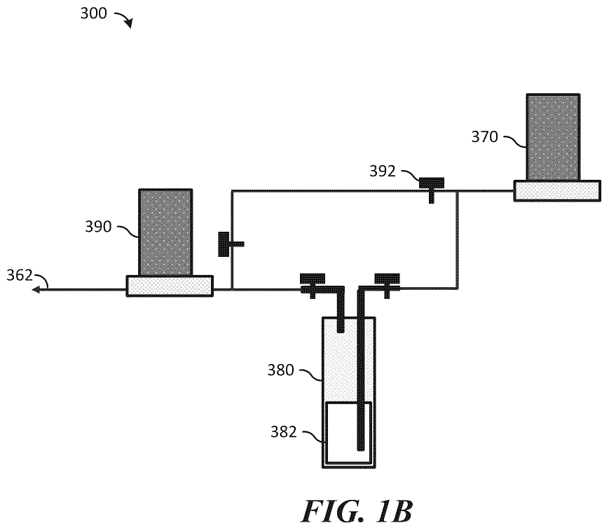

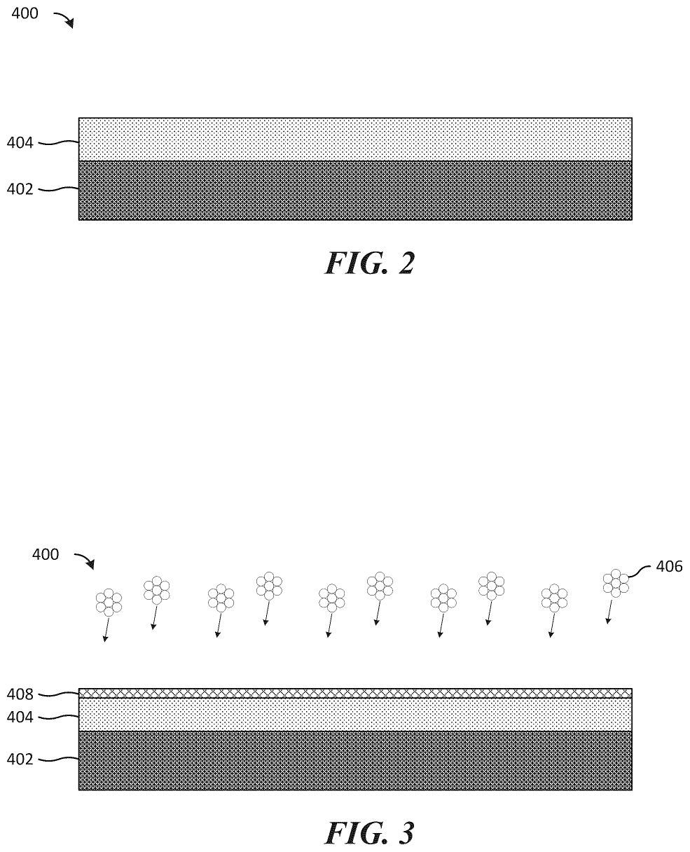

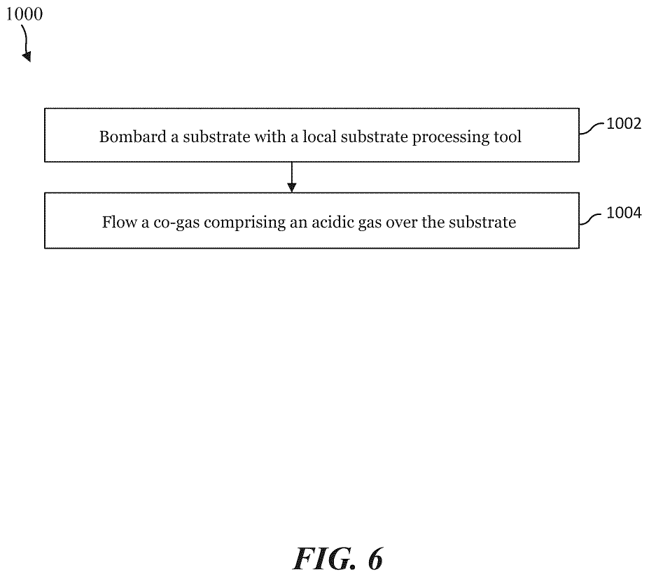

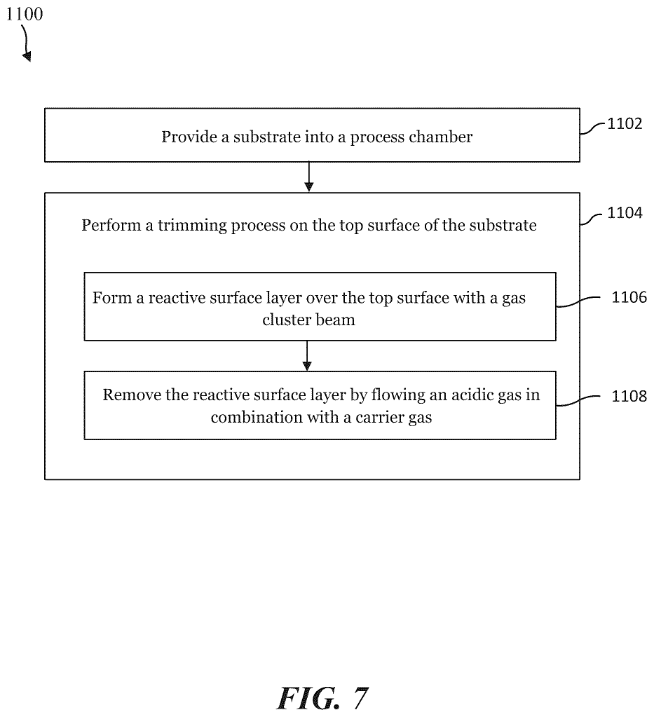

Embodiments of the disclosure are described in the context of the accompanying drawings. An embodiment of a process system will be described using FIG. 1A. An embodiments of a co-gas supply system will be described using FIG. 1B. An embodiment of a trimming process will be described using FIGS. 2, 3, 4A, 4B, and 5. Embodiments of methods for processing a substrate will be described using FIGS. 6 and 7.

FIG. 1A illustrates an example process system 100 for processing a substrate 400, in accordance with some embodiments. The example process system 100 is described for illustrative purposes, and any suitable local substrate processing tool may be used in conjunction with the disclosed embodiments. The process system 100 comprises a vacuum vessel 102, a substrate holder 250 upon which a substrate 400 to be processed is affixed, and vacuum pumping systems 170A, 170B, and 170C. The process system 100 is configured to produce a gas cluster beam for treating the substrate 400.

The vacuum vessel 102 comprises three communicating chambers, namely, a source chamber 104, an ionization/acceleration chamber 106, and a process chamber 108 to provide a reduced-pressure enclosure. The three chambers are evacuated to suitable operating pressures by vacuum pumping systems 170A, 170B, and 170C, respectively. In the three communicating chambers 104, 106, 108, a gas cluster beam can be formed in the first chamber (source chamber 104), while an ionized gas cluster beam can be formed in the second chamber (ionization/acceleration chamber 106) wherein the gas cluster beam is ionized and accelerated. Then, in the third chamber (process chamber 108), the accelerated gas cluster beam may be utilized to treat substrate 400.

In one or more examples, the process system 100 can comprise one or more gas sources configured to introduce one or more gases or mixture of gases to vacuum vessel 102. For example, a first gas composition stored in a first gas source 111 is admitted under pressure through a first gas control valve 113A to a gas metering valve or valves 113. In various embodiments, the first gas composition comprises fluorine, for example nitrogen trifluoride (NF₃), tetrafluoromethane (CF₄), sulfur hexafluoride (SF₆), methyl fluoride (CH₃F), fluoromethane (CH₂F₂), trifluoromethane (CHF₃), silicon tetrafluoride (SiF₄), fluorine (F₂), the like, or a combination thereof. Additionally, for example, a second gas composition stored in a second gas source 112 may be admitted under pressure through a second gas control valve 113B to the gas metering valve or valves 113. Further, for example, the first gas composition or second gas composition or both can include a condensable inert gas, carrier gas or dilution gas. For example, the inert gas, carrier gas or dilution gas can include a noble gas, i.e., He, Ne, Ar, Kr, Xe, or Rn.

Furthermore, the first gas source 111 and the second gas source 112 may be used either alone or in combination with one another to produce ionized clusters. The high pressure, condensable gas comprising the first gas composition or the second gas composition or both is introduced through gas feed tube 114 into stagnation chamber 116 and is ejected into the substantially lower pressure vacuum through a properly shaped nozzle 110. As a result of the expansion of the high pressure, condensable gas from the stagnation chamber 116 to the lower pressure region of the source chamber 104, the gas velocity accelerates to supersonic speeds and gas cluster beam 118 emanates from nozzle 110.

The inherent cooling of the jet as static enthalpy is exchanged for kinetic energy, which results from the expansion in the jet, causes a portion of the gas jet to condense and form a gas cluster beam 118 having clusters, each consisting of from several to several thousand weakly bound atoms or molecules. A gas skimmer 120, positioned downstream from the exit of the nozzle 110 between the source chamber 104 and ionization/acceleration chamber 106, partially separates the gas molecules on the peripheral edge of the gas cluster beam 118, that may not have condensed into a cluster, from the gas molecules in the core of the gas cluster beam 118, that may have formed clusters. Among other reasons, this selection of a portion of gas cluster beam 118 can lead to a reduction in the pressure in the downstream regions where higher pressures may be detrimental (e.g., the ionizer 122 and process chamber 108). Furthermore, the gas skimmer 120 determines an initial dimension for the gas cluster beam entering the ionization/acceleration chamber 106. In an example, the process system 100 may also include multiple nozzles with one or more skimmer openings.

After the gas cluster beam 118 has been formed in the source chamber 104, the constituent gas clusters in gas cluster beam 118 are ionized by ionizer 122 to form gas cluster ionized beam 128. The ionizer 122 may include an electron impact ionizer that produces electrons from one or more filaments 124, which are accelerated and directed to collide with the gas clusters in the gas cluster beam 118 inside the ionization/acceleration chamber 106. Upon collisional impact with the gas cluster, electrons of sufficient energy eject electrons from molecules in the gas clusters to generate ionized molecules. The ionization of gas clusters can lead to a population of charged gas cluster ions, generally having a net positive charge.

Beam electronics 130 are utilized to ionize, extract, accelerate, and focus the gas cluster beam (GCB) 128. The beam electronics 130 include a filament power supply 136 that provides a voltage to heat the ionizer filament 124. The beam electronics 130 also include an extraction power supply 138 that provides a bias voltage to bias at least one of the high voltage electrodes 126 to extract ions from the ionizing region of ionizer 122 and to form the GCB 128. Additionally, the beam electronics 130 include a set of suitably biased high voltage electrodes 126 in the ionization/acceleration chamber 106 that extracts the cluster ions from the ionizer 122. The high voltage electrodes 126 then accelerate the extracted cluster ions to a desired energy and focus them to form the GCB 128. The kinetic energy of the cluster ions in GCB 128 may range from about 1000 electron volts (1 keV) to several tens of keV. For example, GCB 128 can be accelerated to an energy in a range of 1 to 100 keV.

The beam electronics 130 may further include an anode power supply 134 that provides a voltage to an anode of ionizer 122 for accelerating electrons emitted from ionizer filament 124 and causes the electrons to bombard the gas clusters in gas cluster beam 118, which produces cluster ions. Furthermore, the beam electronics 130 can include an accelerator power supply 140 that provides a voltage to bias one of the high voltage electrodes 126 with respect to the ionizer 122. The beam electronics 130 can also include lens power supplies 142, 144 that may be provided to bias some of the high voltage electrodes 126 with potentials to focus the GCB 128.

A beam filter 146 in the ionization/acceleration chamber 106 downstream of the high voltage electrodes 126 can be utilized to eliminate monomers, or monomers and light cluster ions, from the GCB 128 to form a filtered GCB 128A that enters the process chamber 108. In one example the beam filter 146 substantially reduces the number of clusters having 100 or less atoms or molecules or both. The beam filter 146 may comprise a magnet assembly for imposing a magnetic field across the GCB 128 to aid in the filtering process.

A beam gate 148 is disposed in the path of GCB 128 in the ionization/acceleration chamber 106. Beam gate 148 has an open state in which the GCB 128 is permitted to pass from the ionization/acceleration chamber 106 to the process chamber 108 to form the GCB 128A, and a closed state in which the GCB 128 is blocked from entering the process chamber 108. A control cable conducts control signals from control system 190 to beam gate 148. The control signals controllably switch beam gate 148 between the open or closed states.

A substrate 400, which may be a wafer or semiconductor wafer, a lithium-containing substrate, a flat panel display (FPD), a liquid crystal display (LCD), or other substrate to be processed by GCB processing, is disposed in the path of the GCB 128A in the process chamber 108. Because most applications contemplate the processing of large substrates with spatially uniform results, a scanning system may be desirable to uniformly scan the GCB 128A across large areas to produce spatially homogeneous results.

In various examples, the process system 100 comprises a X-Y positioning table 253 operable to hold and move a substrate 400 in two axes, effectively scanning the substrate 400 relative to the GCB 128A. For example, the X-motion can include motion into and out of the plane of the paper, and the Y-motion can include motion along direction 264.

The GCB 128A impacts the substrate 400 at a projected impact region 286 on a surface of the substrate 400, and at an angle of beam incidence 266 with respect to the surface of substrate 400. By X-Y motion, the X-Y positioning table 253 can position each portion of a surface of the substrate 400 in the path of GCB 128A so that every region of the surface may be made to coincide with the projected impact region 286 for processing by the GCB 128A. An X-Y controller 262 provides electrical signals to the X-Y positioning table 253 through an electrical cable for controlling the position and velocity in each of X-axis and Y-axis directions. The X-Y controller 262 receives control signals from, and is operable by, control system 190 through an electrical cable. X-Y positioning table 253 moves by continuous motion or by stepwise motion according to conventional X-Y table positioning technology to position different regions of the substrate 400 within the projected impact region 286. In one or more examples, X-Y positioning table 253 is programmably operable by the control system 190 to scan, with programmable velocity, any portion of the substrate 400 through the projected impact region 286 for GCB processing by the GCB 128A.

The substrate holding surface 254 of positioning table 253 is electrically conductive and is connected to a dosimetry processor operated by control system 190. An electrically insulating layer 255 of positioning table 253 isolates the substrate 400 and substrate holding surface 254 from the base portion 260 of the positioning table 253. Electrical charge induced in the substrate 400 by the impinging GCB 128A is conducted through substrate 400 and substrate holding surface 254. A signal may be coupled through the positioning table 253 to control system 190 for dosimetry measurement.

Depending on the target gas flow rate of the trimming process, the target pressure in the process chamber 108 may be selected to be in a range of 0.001 mTorr to about 0.1 mTorr, in various examples. During gas cluster formation, the ratio of the pressures at the intake to the pressure at the output of each nozzle 110 is advantageously high, for example, greater than 10. In various examples, the ratio of the pressures at the intake to the pressure at the output of each nozzle 110 exceeds 1000.

The process chamber 108 further comprises a gas inlet 362 that is coupled to a co-gas supply system 300. The gas inlet 362 provides a co-gas (e.g., an acidic gas such as pentafluoropropionic acid, trifluoroacetic acid, acetic acid, or a propionic acid that contains a carboxylate function group and forms vapor) from the co-gas supply system 300 into the process chamber 108 to react with the substrate 400 in combination with gas clusters from the nozzle assembly 308. In some embodiments, the gas inlet 362 has a diameter in a range of 5 mm to 50 mm. This may be advantageous by producing a smoother surface and reducing or eliminating the degradation in surface crystallinity of the substrate 400.

A beam current sensor may be disposed beyond the substrate holder 250 in the path of the GCB 128A so as to intercept a sample of the GCB 128A when the substrate holder 250 is scanned out of the path of the GCB 128A. The beam current sensor is typically a Faraday cup or the like, closed except for a beam-entry opening, and is typically affixed to the wall of the vacuum vessel 102 with an electrically insulating mount.

As shown in FIG. 1A, control system 190 couples to the X-Y positioning table 253 through electrical cable and controls the X-Y controller 262 in order to place the substrate 400 into or out of the GCB 128A and to scan the substrate 400 uniformly relative to the GCB 128A to achieve desired processing of the substrate 400 by the GCB 128A. The control system 190 may receive the sampled beam current collected by a beam current sensor by way of an electrical cable and may thereby monitor the GCB and controls the GCB dose received by the substrate 400 by removing the substrate 400 from the GCB 128A when a predetermined dose has been delivered.

In operation, the control system 190 signals the opening of the beam gate 148 to irradiate the substrate 400 with the GCB 128A. The control system 190 monitors measurements of the GCB current collected by the substrate 400 in order to compute the accumulated dose received by the substrate 400. When the dose received by the substrate 400 reaches a predetermined dose, the control system 190 closes the beam gate 148 and processing of the substrate 400 is complete. Based upon measurements of the GCB dose received for a given area of the substrate 400, the control system 190 can adjust the scan velocity in order to achieve an appropriate beam dwell time to treat different regions of the substrate 400.

In an example, the GCB 128A may be scanned at a constant velocity in a fixed pattern across the surface of the substrate 400; however, the GCB intensity is modulated (may be referred to as Z-axis modulation) to deliver an intentionally non-uniform dose to the sample. The GCB intensity may be modulated in the Process system 100′ by any of a variety of methods, including varying the gas flow from a GCB source supply; modulating the ionizer by either varying a filament voltage or varying an anode voltage; modulating the lens focus by varying lens voltages; or mechanically blocking a portion of the GCB with a variable beam block, adjustable shutter, or variable aperture. The modulating variations may be continuous analog variations or may be time modulated switching or gating.

The process chamber 108 may further include an in-situ metrology system. For example, the in-situ metrology system may include an optical diagnostic system having an optical transmitter 280 and optical receiver 282 configured to illuminate substrate 400 with an incident optical signal 284 and to receive a scattered optical signal 288 from substrate 400, respectively. The optical diagnostic system comprises optical windows to permit the passage of the incident optical signal 284 and the scattered optical signal 288 into and out of the process chamber 108. Furthermore, the optical transmitter 280 and the optical receiver 282 may comprise transmitting and receiving optics, respectively. The optical transmitter 280 receives, and is responsive to, controlling electrical signals from the control system 190. The optical receiver 282 returns measurement signals to the control system 190.

In various examples, the in-situ metrology system may comprise any instrument configured to monitor the progress of the GCB processing. In an example, the in-situ metrology system may constitute an optical scatterometry system. The scatterometry system may include a scatterometer, incorporating beam profile ellipsometry (ellipsometer) and beam profile reflectometry (reflectometer.

FIG. 1B illustrates a diagram of an example co-gas supply system 300, in accordance with some embodiments. The co-gas supply system 300 supplies an acidic gas to a process chamber of a suitable local substrate processing tool (e.g., to the process chamber 108 of the example process system 100 (see above, FIG. 1A)) by flowing a carrier gas through an acidic liquid. The co-gas supply system 300 comprises a carrier gas mass flow controller (MFC) 370, a bubbler 380, a vapor pressure controller (VPC) 390, and valves 392 on lines coupling the components of the co-gas supply system 300 together. One or more valves 392 may be on a gas line coupling the carrier gas mass flow controller 370 with the bubbler 380, one or more valves 392 may be on a gas line coupling the carrier gas mass flow controller 370 with the vapor pressure controller (VPC) 390, and one or more valves 392 may be on a gas line coupling the bubbler 380 with the vapor pressure controller (VPC) 390. The one or more valves 392 may be opened and closed to suitable degrees in order to control gas flow between the carrier gas mass flow controller (MFC) 370, the bubbler 380, and the vapor pressure controller (VPC) 390. Although FIG. 1B illustrates one example of a co-gas supply system 300, any suitable co-gas supply system may be used to supply a co-gas to the process chamber 108, and all such combinations are within the scope of the disclosed embodiments.

The carrier gas mass flow controller 370 supplies a carrier gas (e.g., argon (Ar), nitrogen (N₂), helium (He), the like, or a combination thereof) to the bubbler 380 and the vapor pressure controller (VPC) 390 through respective gas lines. The carrier gas mass flow controller 370 may be configured to provide a suitable flow of the carrier gas (e.g., 20 sccm of argon (Ar) or helium (He)) into the bubbler 380, which contains an acidic liquid 382 (e.g., pentafluoropropionic acid). The bubbler 380 mixes the carrier gas with the acidic liquid 382 to form an acidic gas, which is flowed to the vapor pressure controller (VPC) 390. Next, the vapor pressure controller (VPC) 390 maintains a constant concentration of the acidic gas with the carrier gas downstream of the bubbler 380. The acidic gas and carrier gas then flow from the vapor pressure controller (VPC) 390 through another gas line to the gas inlet 362 and into the process chamber 108 (see above, FIG. 1A).

FIGS. 2, 3, 4A, and 5 illustrate cross-sectional views of a substrate 400 during intermediate stages of a trimming process, in accordance with some embodiments. FIG. 2 illustrates a substrate 400 comprising a bottom layer 402 and a lithium-comprising layer 404 over the bottom layer 402. The substrate 400 may be provided into a process chamber, such as the process chamber 108; see above, FIG. 1A. In various embodiments, the bottom layer 402 is a silicon wafer, or a silicon-on-insulator (SOI) wafer. In certain embodiments, the bottom layer 402 comprises silicon germanium, silicon carbide, gallium arsenide, gallium nitride, or other compound semiconductors. In other embodiments, the bottom layer 402 comprises heterogeneous layers such as silicon germanium on silicon, gallium nitride on silicon, silicon carbon on silicon, as well layers of silicon on a silicon or SOI substrate. In various embodiments, the bottom layer 402 is patterned or embedded in other components of an electronic device. In some embodiments, the bottom layer 402 comprises conductive features (e.g., metal lines, not illustrated) embedded therein. The conductive features may be electrically coupled to active devices (not illustrated) further embedded in the bottom layer 402. In still other embodiments, the bottom layer 402 comprises the same materials as the lithium-comprising layer 404 or is absent.

In some embodiments, the lithium-comprising layer 404 comprises lithium tantalate (LiTaO₃), lithium niobate (LiNbO₃), the like, or a combination thereof. The lithium-comprising layer 404 may be used for the manufacturing of one or more piezoelectric devices by using the piezoelectric effect to convert electrical energy into mechanical motion or vice versa, as the lithium-containing material may have advantageous piezoelectric properties such as high electromechanical coupling coefficients and stable temperature behavior. It may be advantageous to trim or etch the lithium-containing material with a gas cluster beam process, such as a process with nitrogen trifluoride (NF₃) gas clusters followed by a chemical mechanical polish (CMP), a two-step argon (Ar) gas cluster beam process, or a nitrogen trifluoride-doped argon gas cluster beam process. However, these processes may provide less benefit on throughput and have rougher surfaces and/or a gas cluster beam influenced layer (e.g., a layer with degradation in surface crystallinity) that deteriorates device performance. As such, it may be advantageous to trim the lithium-comprising layer 404 with a gas cluster beam enhanced with a co-gas (e.g., an acidic gas such as pentafluoropropionic acid) and thereby smooth the top surface of the lithium-comprising layer 404.

In FIG. 3, the lithium-comprising layer 404 is bombarded with gas clusters 406 from a gas cluster beam, in accordance with some embodiments. The bombardment of the substrate 400 by the gas clusters 406 of the gas cluster beam may be performed in, for example, a process system 100 (see above, FIG. 1A). However, any suitable system for gas cluster beam bombardment may be used to bombard the lithium-comprising layer 404 with gas clusters 406.

In various embodiments, the gas clusters 406 comprise fluorine. For example, the gas clusters 406 may be generated using nitrogen trifluoride (NF₃) as a gas cluster beam precursor gas. However, the gas clusters 406 may be generated with any suitable gas.

The gas clusters 406 react with the top surface of the lithium-comprising layer 404 to form a byproduct layer 408. In various embodiments, the byproduct layer 408 comprises lithium fluoride (LiF), an amorphous oxide layer, the like, or a combination thereof. As an example, when the lithium-comprising layer 404 comprises lithium tantalate (LiTaO₃), the byproduct layer 408 comprises an amorphous tantalum oxide (TaOₓ) layer. As another example, when the lithium-comprising layer 404 comprises lithium niobate (LiNbO₃), the byproduct layer 408 comprises an amorphous niobium oxide (NbOₓ) layer.

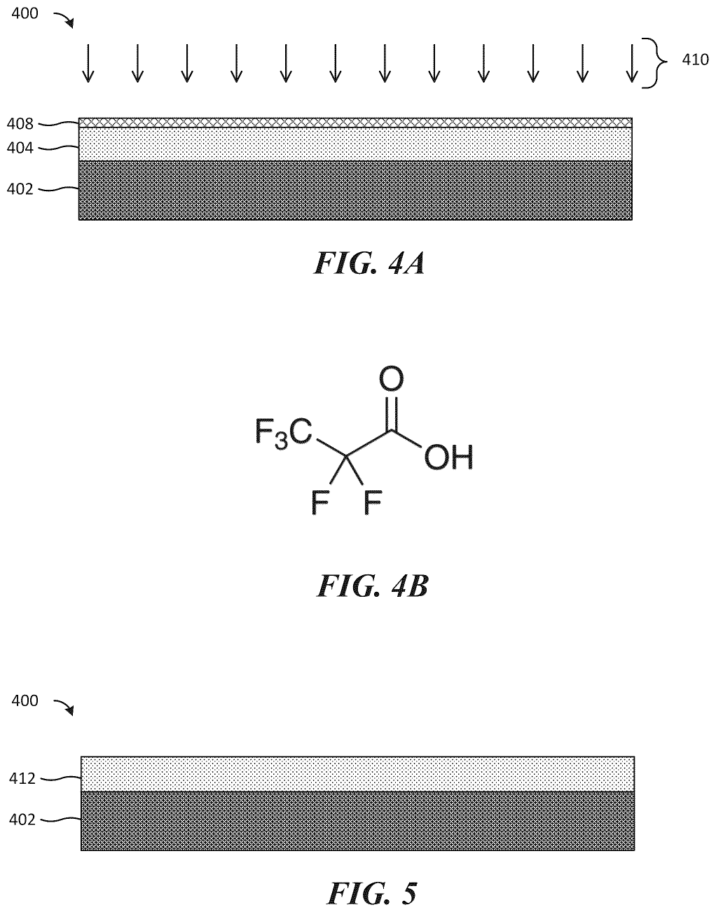

The byproduct layer 408 may have a reactive surface that enhances a subsequent removal of the amorphous oxide by flowing a co-gas (see below, FIG. 4A). A possible reaction mechanism for an example of the lithium-comprising layer 404 comprising lithium tantalate (LiTaO₃) and the gas clusters 406 comprising nitrogen trifluoride (NF₃) is:

LiTaO₃+NF₃ GCB→TaOₓ+LiF+F*+N₂

As shown above, the nitrogen trifluoride from the gas cluster beam reacts with the lithium tantalate (LiTaO₃) to form an amorphous tantalum oxide (TaOₓ) layer, lithium fluoride (LiF), fluorine radicals (F*), and nitrogen (N₂) gas. A possible reaction mechanism for an example of the lithium-comprising layer 404 comprising lithium niobate (LiNbO₃) and the gas clusters 406 comprising nitrogen trifluoride (NF₃) is:

LiNbO₃+NF₃ GCB→NbOₓ+LiF+F*+N₂

As shown above, the nitrogen trifluoride from the gas cluster beam reacts with the lithium niobate (LiNbO₃) to form an amorphous niobium oxide (NbOₓ) layer, lithium fluoride (LiF), fluorine radicals (F*), and nitrogen (N₂) gas.

Next, in FIG. 4A, a co-gas 410 is flowed over the substrate 400, in accordance with some embodiments. The co-gas 410 comprises an acidic gas, such as pentafluoropropionic acid (PFPrA), trifluoroacetic acid (TFA), heptafluorobutyric acid, perfluoropentanoic acid, perfluorohexanoic acid, perfluoroheptanoic acid, acetic acid, a propionic acid that contains a carboxylate function group and forms vapor, the like, or a combination thereof. As an example, FIG. 4B illustrates a chemical diagram of pentafluoropropionic acid (PFPrA (C₂F₅COOH)). In various embodiments, the co-gas 410 further comprises a carrier gas such as argon (Ar), helium (He), nitrogen (N₂), the like, or a combination thereof. The carrier gas may be used to carry the acidic gas into the process chamber (e.g., a process chamber 108; see above, FIG. 1A). Using an inert gas such as helium (He) or argon (Ar) may be advantageous by reducing or preventing a reaction between the acidic gas of the co-gas 410 and the gas clusters 406 before the gas clusters 406 react with the substrate. The acidic gas may react with the byproduct layer 408 and remove fluorine contamination from the amorphous oxide layer of the byproduct layer 408. Remaining amorphous oxide on the substrate 400, if any, may be thinner and have reduced fluorine contamination, resulting in a smoother surface and reduced degradation in surface crystallinity.

In various embodiments, the co-gas 410 is flowed at a flow rate in a range of 10 sccm to 400 sccm, such as 20 sccm, under a pressure in a range of 0.1 mTorr to 0.001 mTorr, and for a duration of 60 seconds to 3600 seconds, and at a temperature in a range of 25° C. to 100° C. However, any suitable process conditions may be used to flow the co-gas 410.

The co-gas 410 may react with the byproduct layer 408 and remove amorphous oxide and lithium fluoride. A possible reaction mechanism for an example of the byproduct layer 408 comprising tantalum oxide (TaOₓ) and lithium fluoride (LiF) and the gas clusters 406 comprising pentafluoropropionic acid (C₂F₅COOH) is:

TaOₓ+LiF+F*+C₂F₅COOH→Ta(C₂F₅COO)₅+LiF+HF+H₂O

As shown above, the tantalum oxide (TaOₓ) and lithium fluoride (LiF) may react with remaining fluorine radicals (F*) and pentafluoropropionic acid (C₂F₅COOH) to produce gaseous Ta(C₂F₅COO)₅, gaseous or liquid hydrogen fluoride (HF), solid lithium fluoride (LiF) that may be dissolved in HF, and gaseous or liquid water (H₂O). As such, the reactive surface of the byproduct layer 408 generated by the gas clusters 406 comprising nitrogen trifluoride (NF₃) (see above, FIG. 3) enhances the removal of the amorphous tantalum oxide (TaOₓ) by a reaction of the pentafluoropropionic acid (C₂F₅COOH) with remaining fluorine. A possible reaction mechanism for an example of the byproduct layer 408 comprising niobium oxide (NbOₓ) and lithium fluoride (LiF) and the gas clusters 406 comprising pentafluoropropionic acid (C₂F₅COOH) is:

NbOₓ+LiF+F*+C₂F₅COOH→Nb(C₂F₅COO)₅+LiF+HF+H₂O

As shown above, the niobium oxide (NbOₓ) and lithium fluoride (LiF) may react with remaining fluorine radicals (F*) and pentafluoropropionic acid (C₂F₅COOH) to produce gaseous Nb(C₂F₅COO) s, gaseous or liquid hydrogen fluoride (HF), solid lithium fluoride (LiF) that may be dissolved in HF, and gaseous or liquid water (H₂O). As such, the reactive surface of the byproduct layer 408 (also referred to as a reactive surface layer) generated by the gas clusters 206 comprising nitrogen trifluoride (NF₃) (see above, FIG. 3) enhances the removal of the amorphous niobium oxide (NbOₓ) by a reaction of the pentafluoropropionic acid (C₂F₅COOH) with remaining fluorine.

Next, FIG. 5 illustrates the substrate 400 after the byproduct layer 408 has been removed by flowing the co-gas 410 (see above, FIG. 4A), in accordance with some embodiments. The trimming process by the bombardment with gas clusters (see above, FIG. 3) and the flowing the co-gas 410 may trim the substrate 400 by a vertical distance in a range of 20 nm to 50 nm while producing a smoother surface and reducing or eliminating a degradation in surface crystallinity. Experimental results have demonstrated that using an acidic co-gas such as pentafluoropropionic acid with gas clusters comprising fluorine can increase the etch rate of a lithium tantalate substrate by 30% and reduce surface roughness of the lithium tantalate substrate by 50%.

Although FIGS. 3 and 4A illustrate bombarding the substrate 400 with gas clusters 406 being followed by flowing the co-gas 410, it should be understood that bombarding the substrate 400 with gas clusters 406 and flowing the co-gas 410 may be performed successively, simultaneously, in partially overlapping steps, or in a combination thereof, such as in a cyclic process in which each cycle comprises a step of bombarding the substrate 400 with gas clusters 406 and a step of flowing the co-gas 410. Additionally, the trimming process may comprise any suitable number of cycles of bombarding the substrate 400 with gas clusters 406 and flowing the co-gas 410 successively, simultaneously, or in overlapping steps, and all such combinations are within the scope of the disclosed embodiments.

FIG. 6 illustrates a process flow chart diagram of a method 1000 for processing a substrate, in accordance with some embodiments. In step 1002, a substrate is bombarded with a local substrate processing tool, as described above with respect to FIG. 3. The substrate includes lithium. In an embodiment, the top surface of the substrate includes lithium tantalate. In an embodiment, the top surface of the substrate includes lithium niobate. In an embodiment, the local substrate processing tool includes a gas cluster beam. In an embodiment, the gas cluster beam comprises fluorine.

In step 1004, after bombarding the top surface with the local substrate processing tool, a co-gas including an acidic gas is flowed over the substrate, as described above with respect to FIG. 4A. In an embodiment, the acidic gas includes pentafluoropropionic acid. In an embodiment, flowing the co-gas further includes flowing a carrier gas. In an embodiment, the carrier gas includes helium. In an embodiment, the carrier gas includes argon. In an embodiment, the carrier gas includes nitrogen.

FIG. 7 illustrates a process flow chart diagram of a method 1100 for processing a substrate, in accordance with some embodiments. In step 1102, the substrate is provided into a process chamber, as described above with respect to FIG. 2. A top surface of the substrate includes lithium. In an embodiment, the top surface of the substrate is lithium tantalate. In an embodiment, the reactive surface layer includes amorphous tantalum oxide. In an embodiment, the top surface of the substrate is lithium niobate. In an embodiment, the reactive surface layer includes amorphous niobium oxide.

In step 1104, a trimming process is performed on the top surface of the substrate, as described above with respect to FIGS. 3 and 4A. The trimming process includes steps 1106 and 1108. In step 1106, a reactive surface layer is formed over the top surface with a gas cluster beam, as described above with respect to FIG. 3. In step 1108, the reactive surface layer is removed by flowing an acidic gas in combination with a carrier gas, as described above with respect to FIG. 4A. In an embodiment, the acidic gas includes pentafluoropropionic acid. In an embodiment, the carrier gas includes helium, argon, or nitrogen.

Example embodiments of the disclosure are summarized here. Other embodiments can also be understood from the entirety of the specification as well as the claims filed herein.

Example 1. A method for processing a substrate, the method including: bombarding the substrate with a local substrate processing tool, a top surface of the substrate including lithium; and after bombarding the top surface with the local substrate processing tool, flowing a co-gas including an acidic gas over the substrate.

Example 2. The method of example 1, where the top surface of the substrate includes lithium tantalate.

Example 3. The method of one of examples 1 or 2, where the top surface of the substrate includes lithium niobate.

Example 4. The method of one of examples 1 to 3, where the acidic gas includes pentafluoropropionic acid.

Example 5. The method of one of examples 1 to 4, where flowing the co-gas further includes flowing a carrier gas.

Example 6. The method of example 5, where the carrier gas includes helium.

Example 7. The method of one of examples 5 or 6, where the carrier gas includes argon.

Example 8. The method of one of examples 5 to 7, where the carrier gas includes nitrogen.

Example 9. The method of one of examples 1 to 8, where the local substrate processing tool includes a gas cluster beam.

Example 10. The method of example 9, where the gas cluster beam includes fluorine.

Example 11. A method for processing a substrate, the method including: providing the substrate into a process chamber, a top surface of the substrate including lithium; and performing a trimming process on the top surface of the substrate, the trimming process including: forming a reactive surface layer over the top surface with a gas cluster beam; and removing the reactive surface layer by flowing an acidic gas in combination with a carrier gas.

Example 12. The method of example 11, where the top surface of the substrate is lithium tantalate.

Example 13. The method of example 12, where the reactive surface layer includes amorphous tantalum oxide.

Example 14. The method of example 11, where the top surface of the substrate is lithium niobate.

Example 15. The method of example 14, where the reactive surface layer includes amorphous niobium oxide.

Example 16. The method of one of examples 11 to 15, where the acidic gas includes pentafluoropropionic acid.

Example 17. The method of one of examples 11 to 16, where the carrier gas includes helium, argon, or nitrogen.

Example 18. A system including: a process chamber, the process chamber including a substrate holder; a gas flow system coupled with the process chamber, the gas flow system being configured to bombard a substrate disposed on the substrate holder with a flux of gas clusters; and a co-gas supply system, the co-gas supply system being configured to supply an acidic co-gas to the substrate, the acidic co-gas reacting with a top surface of the substrate exposed to the gas clusters.

Example 19. The system of example 18, where the acidic co-gas includes pentafluoropropionic acid.

Example 20. The system of one of examples 18 or 19, where the gas flow system is configured to bombard the substrate with gas clusters including fluorine.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
bombarding the substrate with a local substrate processing tool, a top surface of the substrate comprising lithium; and
after bombarding the top surface with the local substrate processing tool, flowing a co-gas comprising an acidic gas over the substrate.

2. The method of claim 1, wherein the top surface of the substrate comprises lithium tantalate.

3. The method of claim 1, wherein the top surface of the substrate comprises lithium niobate.

4. The method of claim 1, wherein the acidic gas comprises pentafluoropropionic acid.

5. The method of claim 1, wherein flowing the co-gas further comprises flowing a carrier gas.

6. The method of claim 5, wherein the carrier gas comprises helium.

7. The method of claim 5, wherein the carrier gas comprises argon.

8. The method of claim 5, wherein the carrier gas comprises nitrogen.

9. The method of claim 1, wherein the local substrate processing tool comprises a gas cluster beam.

10. The method of claim 9, wherein the gas cluster beam comprises fluorine.

11. A method for processing a substrate, the method comprising:
providing the substrate into a process chamber, a top surface of the substrate comprising lithium; and
performing a trimming process on the top surface of the substrate, the trimming process comprising:
forming a reactive surface layer over the top surface with a gas cluster beam; and
removing the reactive surface layer by flowing an acidic gas in combination with a carrier gas.

12. The method of claim 11, wherein the top surface of the substrate is lithium tantalate.

13. The method of claim 12, wherein the reactive surface layer comprises amorphous tantalum oxide.

14. The method of claim 11, wherein the top surface of the substrate is lithium niobate.

15. The method of claim 14, wherein the reactive surface layer comprises amorphous niobium oxide.

16. The method of claim 11, wherein the acidic gas comprises pentafluoropropionic acid.

17. The method of claim 11, wherein the carrier gas comprises helium, argon, or nitrogen.

18. A system comprising:
a process chamber, the process chamber comprising a substrate holder;
a gas flow system coupled with the process chamber, the gas flow system being configured to bombard a substrate disposed on the substrate holder with a flux of gas clusters; and
a co-gas supply system, the co-gas supply system being configured to supply an acidic co-gas to the substrate, the acidic co-gas reacting with a top surface of the substrate exposed to the gas clusters.

19. The system of claim 18, wherein the acidic co-gas comprises pentafluoropropionic acid.

20. The system of claim 18, wherein the gas flow system is configured to bombard the substrate with gas clusters comprising fluorine.
